(19) United States
(12) Patent Application Publication
(10) Pub. No.: US 2006/0022692 A1
(43) Pub. Date: Feb. 2, 2006

(54) Backside attach probe, components thereof, and methods for making and using same

(76) Inventors: Brock J. LaMeres, Colorado Springs, CO (US); Brent Holcombe, Colorado Springs, CO (US); Kenneth Johnson, Colorado Springs, CO (US)

Correspondence Address: AGILENT TECHNOLOGIES, INC.;Legal Department, DL429, Intellectual Property Administration, P.O. Box 7599, Loveland, CO, 80537-0599, US

(21) Appl. No.: 10/902,405

(22) Filed: Jul. 28, 2004

(51) Int. Cl. G01R 31/02

(52) U.S. Cl. 324/758

(57) ABSTRACT

In a method for probing a grid array package, a probe having a plurality of probe tip spring pins therein is aligned with a plurality of breakout vias on a printed circuit board. The breakout vias are on a side of the printed circuit board opposite a side of the printed circuit board to which the grid array package is attached. The probe tip spring pins are engaged with the breakout vias, and the probe is then mechanically coupled to the printed circuit board to keep the probe tip spring pins engaged with the breakout vias. Various embodiments and methods of constructing the probe are also disclosed.

### BACKGROUND

High signal counts in modern digital systems have driven integrated circuits into grid array packaging. Grid array packaging allows signals to be routed entirely on the inner layers of printed circuit boards (PCBs). While this is advantageous for increasing signal density on a PCB, it presents new challenges for testability of PCBs.

One way to probe a grid array package is to “interpose” between the grid array package and the PCB to which it is mounted. A second way to probe a grid array package is to probe the backside of the PCB to which it is mounted, at breakout vias corresponding to points where the grid array package attaches to traces of the PCB.

One way to probe the backside of a PCB is via a forced connection (i.e., where a user manually presses a probe against the point or points to be probed). Another way to probe the backside of a PCB is via a solder-down connection.

### SUMMARY

One aspect of the invention is embodied in a method for probing a grid array package. The method comprises aligning a probe having a plurality of probe tip spring pins therein with a plurality of breakout vias on a printed circuit board (PCB). The breakout vias are on a side of the PCB opposite a side of the PCB to which the grid array package is attached. After the probe is aligned, the probe tip spring pins are engaged with the breakout vias. The probe is then mechanically coupled to the PCB to keep the probe tip spring pins engaged with the breakout vias.

A second aspect of the invention is embodied in apparatus comprising a probe tip spring pin, an isolation resistor and a wire. The isolation resistor is electrically coupled to the probe tip spring pin, and the wire is electrically coupled to the isolation resistor.

An additional aspect of the invention is embodied in a probe tip spring pin apparatus comprising a sleeve, a plunger and a spring. The sleeve has a first crown tip. The plunger is mechanically retained in the sleeve, and has a second crown tip that is disposed opposite the first crown tip. The spring biases the plunger with respect to the sleeve. The sleeve, spring and plunger provide a conductive path between the first and second crown tips.

Another aspect of the invention is embodied in a probe apparatus comprising a PCB and a probe tip spring pin. The PCB has first and second traces, a via that electrically couples the first and second traces, and upper and lower blind plated holes that respectively intersect the first and second traces. The probe tip spring pin is retained within the upper blind plated hole (and a fixed pin may be retained in the lower blind plated hole).

Yet another aspect of the invention is embodied in a kit for making a probe to probe a grid array package. The kit comprises a substrate with a plurality of holes therein, a mechanism to mechanically couple the substrate to a printed circuit board, and a plurality of probe tip spring pin assemblies that are sized to be fit into the holes in the substrate. Optionally, the mechanism to mechanically couple the substrate to the PCB may be pre-assembled on the substrate.

Other embodiments of the invention are also disclosed.

### BRIEF DESCRIPTION OF THE DRAWINGS

Illustrative and presently preferred embodiments of the invention are illustrated in the drawings, in which:

FIGS. 1 & 2 illustrate the coupling of an exemplary backside attach probe to a PCB;

FIG. 3 illustrates a first exemplary construction of the backside attach probe shown in FIG. 1;

FIG. 4 illustrates, in exploded form, various exemplary layers of the probe portion shown in FIG. 3;

FIG. 5 illustrates a first exemplary elevation of one of the probe tip spring pins shown in FIG. 1;

FIG. 6 illustrates a second exemplary construction of one of the probe tip spring pins shown in FIG. 1;

FIG. 7 illustrates a second exemplary construction of the backside attach probe shown in FIG. 1;

FIG. 8 illustrates an exemplary schematic of a probe tip network;

FIG. 9 illustrates an exemplary probe tip spring pin assembly; and

FIG. 10 illustrates use of the probe tip spring pin assembly shown in FIG. 9 to construct a third exemplary embodiment of the backside attach probe shown in FIG. 1.

### DESCRIPTION OF THE INVENTION

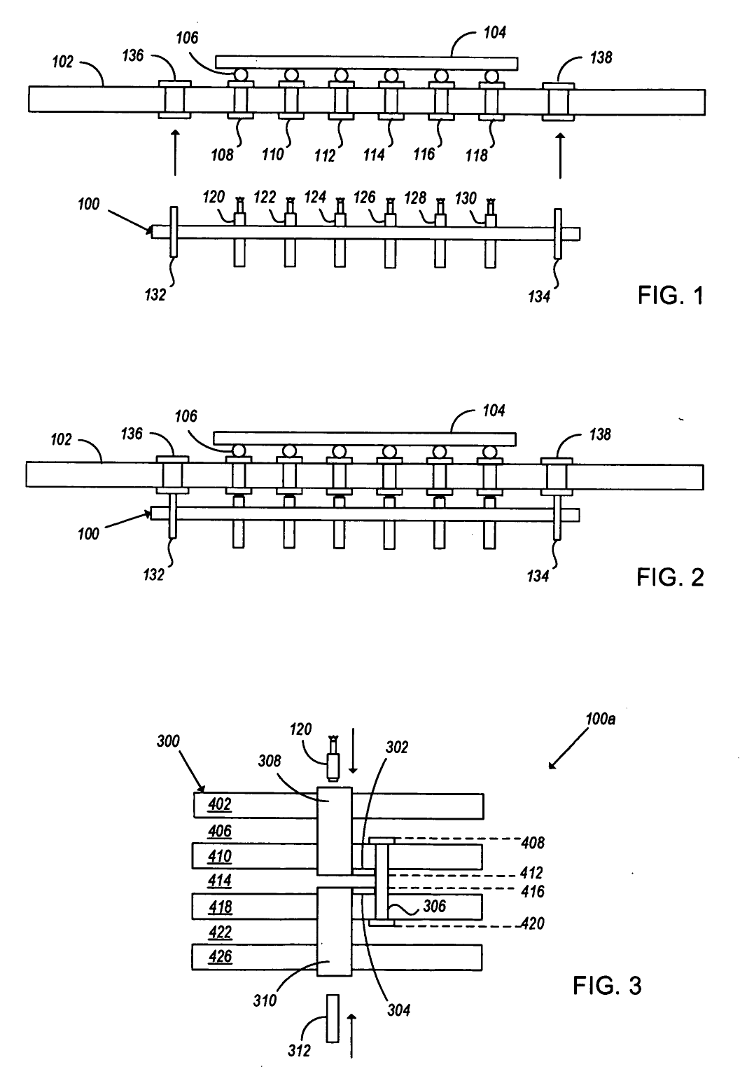

FIGS. 1 & 2 illustrate the coupling of an exemplary backside attach probe 100 to a printed circuit board (PCB) 102.

Attached to the PCB 102 is a grid array package 104. By way of example, and as shown in the figures, the package 104 may be a ball grid array (BGA) package. However, the package 104 could also take other forms (such as that of a land grid array (LGA) package).

The grid array package 104 is attached to the PCB 102 at a number of pads (e.g., pad 106) on one side of the PCB 102. The pads (e.g., 106) to which the package 104 is attached are coupled to a plurality of breakout vias 108, 110, 112, 114, 116, 118 that present on a side of the PCB 102 opposite the side of the PCB to which the package 104 is attached. For purposes of illustration, each of the breakout vias 108-118 is shown to be bounded above and below by a somewhat thick pad (e.g., pad 106). Typically, however, these pads will be very thin. Also, FIG. 1 shows that each of the breakout vias 108-118 is a through-hole type via. Although through-hole vias reduce the lengths of electrical paths between the package 104 and the probe 100, the vias 108-118 need not be through-hole vias, and could for example, traverse only some of the layers of the PCB 102. In this case, the breakout vias would not extend to package 104, and would instead be coupled to package 104 by means of internal traces and/or other vias of PCB 102. Also, if the breakout vias 108-118 are not through-hole type vias, they may not be vertically aligned with the contacts (e.g., solder balls) of package 104, as shown in FIG. 1.

As shown, the probe 100 may comprise a plurality of probe tip spring pins 120-130. The probe 100 may also comprise one or more mechanisms 132, 134 that may be used to mechanically couple the probe 100 to the PCB 102. As shown in FIG. 1, probe 100 comprises two such mechanisms 132, 134, and PCB 102 comprises two corresponding mechanisms 136, 138. However, the number of securing mechanisms 132-138 on the probe 100 and PCB 102 may vary. By way of example, the securing mechanisms 132, 134 of the probe 100 may be pop rivets, and the corresponding mechanisms 136, 138 of the PCB 102 may be through-holes.

To probe the grid array package 104, the probe 100 is first aligned with the plurality of breakout vias 108-118 (see FIG. 1). The probe 100 is then moved toward the PCB 102 until its probe tip spring pins 120-130 engage the PCB's breakout vias 108-118 (see FIG. 2). As the spring pins 120-130 engage the breakout vias 108-118, they apply pressure to the breakout vias 108-118, thereby ensuring good electrical connections with the breakout vias 120-130. At this point, the probe 100 may be mechanically coupled to the PCB 102 to keep the spring pins 120-130 engaged with the breakout vias 108-118. In some embodiments, movement of the probe 100 toward the PCB 102 may cause the securing mechanisms 132, 134 of the probe 100 to automatically engage their corresponding mechanisms 136, 138 on the PCB 102. In other embodiments, the securing mechanisms 132, 134 may require manual engagement.

Providing a probe 100 with probe tip spring pins makes the probe 100 more “user friendly” by giving some relief to its user. That is, the user can worry less that he/she is pressing too hard (and damaging the probe 100) or too soft (and not ensuring a good electrical connection between the probe 100 and breakout vias 108-118).

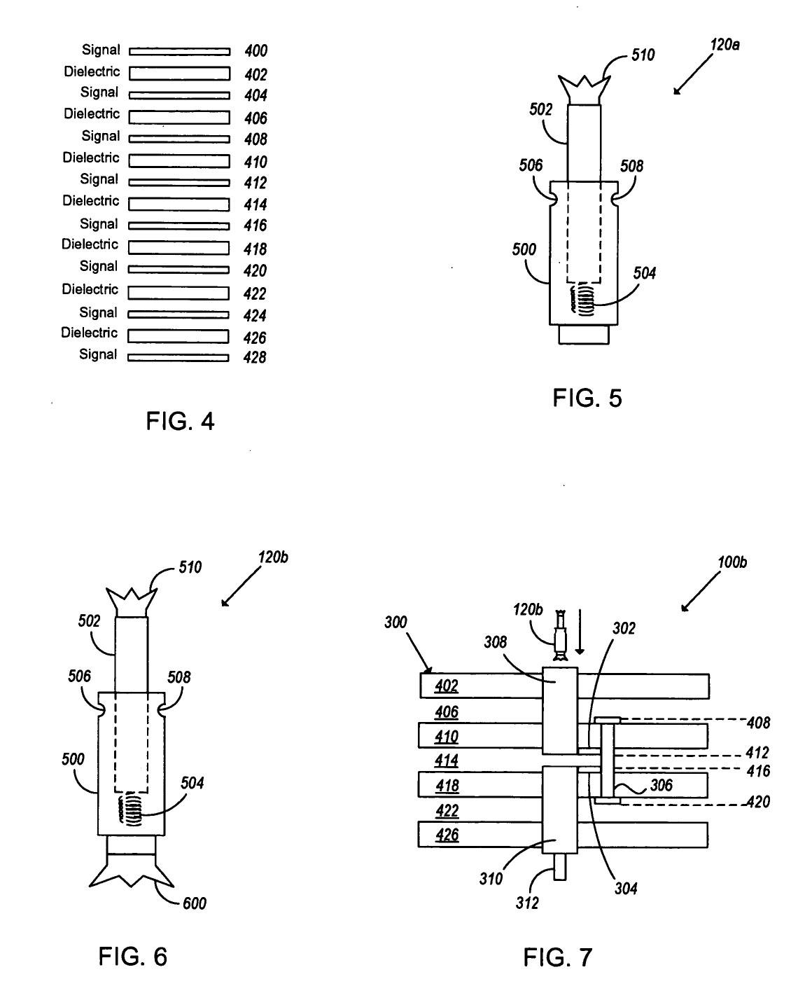

FIG. 3 illustrates a first exemplary construction of the probe 100. As shown, the probe 100a may comprise a PCB 300 having first and second circuit traces 302, 304 that are electrically coupled by a via 306. Preferably, and as shown, the traces 302, 304 are formed as inner traces, and the via 306 is formed as a buried via. Alternately, one or both of the traces 302, 304 could be formed as surface traces, and the via 306 could be formed as either a blind via (i.e., a via drilled from one side of the PCB 300) or a through-hole via. Depending on the types of traces and via employed, the traces and via may be formed prior to, or during, assembly of the various layers of the PCB 300. FIG. 4 illustrates, in exploded form, various exemplary layers 400-428 of the probe portion shown in FIG. 3. Note that the layers 400-428 comprise alternating signal and dielectric layers (with only some of these layers being specifically referenced in FIG. 3).

Referring again to FIG. 3, the PCB 300 of the probe 100a comprises upper and lower blind plated holes 308, 310 that respectively intersect the first and second traces 302, 304. In one embodiment, the blind plated holes 308, 310 are formed by drilling first and second holes into the PCB 300, and then spin-coating the surfaces of the holes with a conductive material.

After formation of the blind plated holes 308, 310, a probe tip spring pin 120 is inserted into the upper blind plated hole 308. The spring pin 120 may be retained within the hole 308 in a number of ways. For example, the hole 308 and spring pin 120 could be sized to enable press fitting of the spring pin 120. Alternately, the body of the spring pin 120 could be soldered (or otherwise conductively adhered) to the hole's plating, or to a conductive pad formed at the mouth of the hole 308.

To facilitate the attach of test instrument leads or cabling to the probe 100a, a fixed pin 312 may be inserted into the lower blind plated hole 310, and retained therein using any of the ways used to retain spring pin 120 in hole 308. Although FIG. 3 shows that the spring pin 120 and fixed pin 312 are aligned, this need not be the case. For example, the lower blind plated holes 310 of the probe 100a could be formed at a different pitch or in a different pattern than the probe's upper blind plated holes 308, thereby enabling the probe 100a to be coupled to a particular connector of a test instrument cable, or providing more spacing between the lower blind plated holes 310 so that a user can more easily probe individual ones of a grid array package's signals. In alternate embodiments of the probe 100a, something other than a fixed pin may be inserted in the probe's lower holes 310.

FIG. 5 illustrates a first exemplary elevation of one of the probe tip spring pins 120 shown in FIGS. 1-3. By way of example, the probe tip spring pin 120a comprises a sleeve 500, a plunger 502, and a spring 504. The spring 504 and plunger 502 are inserted into and mechanically retained in the sleeve 500 (e.g., by detents 506, 508 created after the plunger 502 is inserted into the sleeve 500), with the spring biasing the plunger 502 with respect to the sleeve 500. Optionally, the plunger 502 may be provided with a crown tip 510. In one embodiment, the crown tip 510 is an integral extension of the plunger's body. In another embodiment, the crown tip 510 is soldered or otherwise bonded to the plunger's body.

The components of the probe tip spring pin 120a may be formed from various metallic or composite materials. However, all of the components 500-504 are conductive so that a conductive path is formed between the tip 510 of the plunger 502 and the sleeve 500.

FIG. 6 illustrates a second exemplary construction of one of the probe tip spring pins 120 shown in FIGS. 1-3. As shown, the probe tip spring pin 120b shares many of the same components found in the spring pin 120a. However, the spring pin 120b additionally comprises a second crown tip 600. This second crown tip forms an integral part of, or is conductively bonded to, the spring pin's sleeve 500. The second crown tip 600 is also disposed opposite the first crown tip 510 (i.e., the crown tip of the plunger 502).

Although the crown tips 510, 600 shown in FIGS. 5 & 6 are outwardly flared, they need not be. Further, the diameter of the crown tip 600 is shown to be larger than that of the sleeve 500 (FIG. 6), but it need not be.

FIG. 7 illustrates a second exemplary construction of the backside attach probe 100. The probe 100b differs from the probe 100a (FIG. 3) in that it uses the probe tip spring pin 120b (FIG. 6). When the spring pin 120b is inserted into the blind plated hole 308, the tips of its crown 600 abrade the plating of the hole 308. Depending on the material(s) used to plate the hole 308, as well as the material(s) used to form the spring pin 120b, the crown tip 600 of spring pin 120b may provide better conductivity between the spring pin 120b and hole 308.

As with the spring pin 120 of the probe 100a, the spring pin 120b of the probe 100b may be press fit or soldered into hole 308.

Although the probe 100 (possibly constructed as probe 100a or 100b) may be provided to a user pre-assembled, it may also be provided to a user in kit form. That is, a user may be provided with a PCB 300 (constructed as shown), a plurality of spring pins (e.g., spring pins 120a or 120b), and the mechanism 132, 134 that is used to mechanically couple the probe 100 to the PCB 102. Preferably, the mechanism 132, 134 is pre-assembled to the PCB 300.

So long as the breakout vias 108-118 of a PCB 100 are provided at the same pitch as the upper holes 308 of the probe 100, the user may configure the probe 100 of a kit by inserting probe tip spring pins 120 into holes 308 that are selected to match the layout of the breakout vias 108-118.

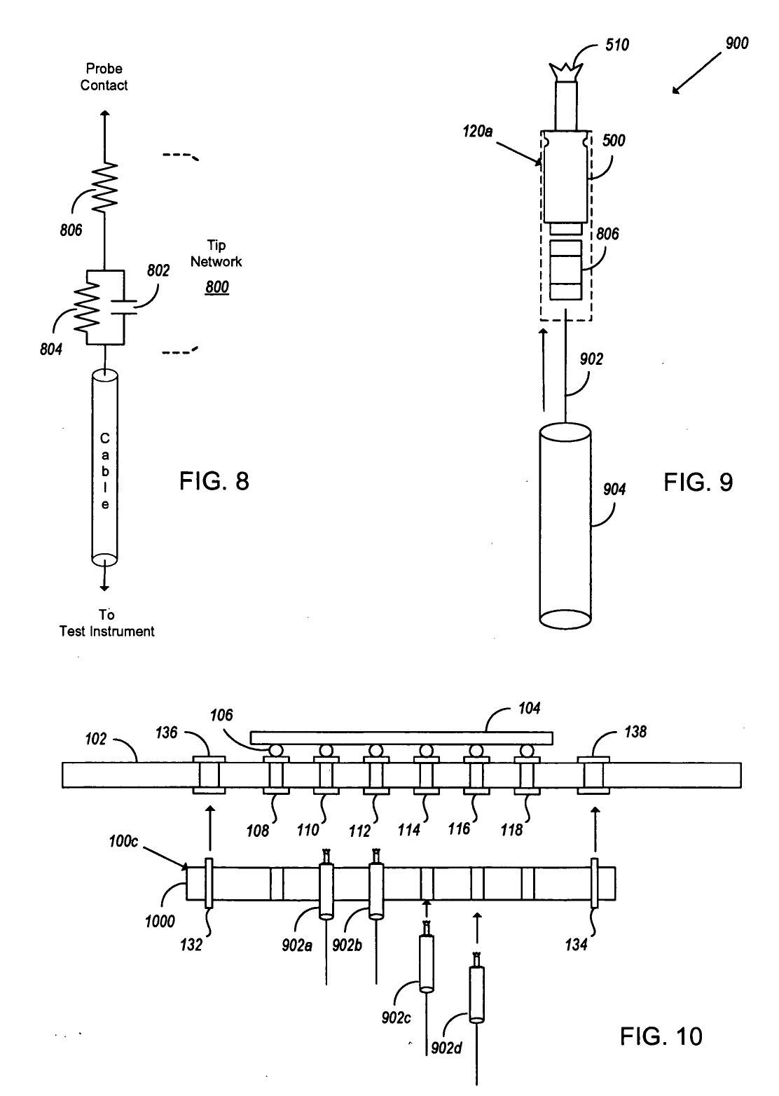

As shown in FIG. 8, the probes or leads of modern test instruments typically comprise a tip network 800. The tip network 800 usually comprises a tip capacitor 802 and tip resistor 804 that form a compensated resistive-divider circuit with the termination impedance of a test instrument. The electrical loading on signals being probed can be reduced by placing the tip network 800 as close as possible to a target signal (i.e., a signal being probed). Placing the tip network 600 closer to a target signal also increases the quality of signals that are sensed by a test instrument (e.g., by reducing signal reflections and “ringing”). However, spatial and capacitive loading problems often make it difficult to place the tip capacitor 802 and tip resistor 804 (which is often on the order of 20 kD) as close to the target signal as desired. As a result, the tip network 800 will sometimes also comprise an isolation resistor 806. The value of this isolation resistor 806 may be on the order of 125Ω. Being of smaller size than the tip resistor 804, and being one component instead of two, the isolation resistor 806 can often be placed much closer to a target signal than the tip capacitor 802 and tip resistor 804.

FIG. 9 illustrates an exemplary probe tip spring pin assembly 900. The assembly 900 comprises a probe tip spring pin 120a, an isolation resistor 806, and a wire 902. The isolation resistor 806 is electrically coupled to the spring pin 120a, and the wire 902 is electrically coupled to the isolation resistor 806. The assembly 900 can be advantageous in that it places the isolation resistor 806 very close to the probe tip 510. By way of example, the isolation resistor 806 may be soldered to the sleeve 500 of the spring pin 120a. Alternately, the isolation resistor 806 could be coupled to the spring pin 120a by means of a conductive adhesive.

Optionally, a portion of the spring pin 120a and some or all of the isolation resistor 806 may be surrounded by non-conductive sheathing 904.

FIG. 10 illustrates use of the probe tip spring pin assembly 900 to construct a third exemplary embodiment of the backside attach probe 100 shown in FIG. 1. As shown, a probe 100c may be configured by inserting a plurality of probe tip spring pin assemblies 900a, 900b, 900c, 900d into holes in a substrate 1000. The holes into which the spring pin assemblies 900a-d are inserted may be selected to match a layout of breakout vias 110-116 that are to be probed. Note that, in the configuration shown in FIG. 10, the user has chosen to probe only some of the signals of grid array package 104.

Before or after insertion of the spring pin assemblies 900a-d into the substrate 1000, the wires 902 of the assemblies 900a-d may be attached to leads or cables of a test instrument. Alternately, the assemblies 900a-d may form integral extensions of a test instrument cable or cables.

The substrate 1000 may be formed of plastic. The non-conductive sleeves 904 of spring pin assemblies 900a-d may also be formed of plastic. In one embodiment of the probe 100c, the plastic of the sleeves 904 is harder than the plastic of the substrate 1000, thereby providing rigidity to the assemblies 900a-d and providing higher friction surfaces for the walls of the holes in the substrate 1000. In this manner, it may be easier for a user to push the spring pin assemblies 900a-d into the substrate 1000, yet difficult for the spring pin assemblies 900a-d to become dislodged from the substrate 1000. As with the probes 100a and 100b, the probe 100c shown in FIG. 10 may be provided in kit form.

While illustrative and presently preferred embodiments of the invention have been described in detail herein, it is to be understood that the inventive concepts may be otherwise variously embodied and employed, and that the appended claims are intended to be construed to include such variations, except as limited by the prior art.

What is claimed is:

1. A method for probing a grid array package, comprising:
aligning a probe, having a plurality of probe tip spring pins therein, with a plurality of breakout vias on a printed circuit board, the breakout vias being on a side of the printed circuit board opposite a side of the printed circuit board to which the grid array package is attached;
engaging the probe tip spring pins with the breakout vias; and
mechanically coupling the probe to the printed circuit board to keep the probe tip spring pins engaged with the breakout vias.

2. The method of claim 1, further comprising configuring the probe, before aligning the probe, by inserting the probe tip spring pins into holes in a substrate of the probe, the holes being selected to match a layout of the breakout vias to be probed.

3. The method of claim 2, wherein at least some of the probe tip spring pins are electrically coupled to isolation resistors, wherein the isolation resistors are coupled to wires, and wherein the probe tip spring pins are inserted into through-holes in the substrate.

4. The method of claim 3, wherein at least portions of the probe tip spring pins and isolation resistors are covered in non-conductive sheathing, the non-conductive sheathing helping to retain the probe tip spring pins in the substrate.

5. The method of claim 2, wherein at least some of the probe tip spring pins are comprised of a sleeve, each sleeve mechanically retaining a plunger, each plunger having a first crown tip and each sleeve having a second crown tip, the method further comprising inserting the second crown tip into one of the selected holes in the substrate.

6. The method of claim 5, wherein the second crown tip has a diameter larger than that of the sleeve.

7. The method of claim 5, wherein the second crown tip has an outwardly flared crown.

8. Apparatus, comprising:
a probe tip spring pin;
an isolation resistor, electrically coupled to the probe tip spring pin; and
a wire, electrically coupled to the isolation resistor.

9. The apparatus of claim 8, wherein the probe tip spring pin further comprises non-conductive sheathing surrounding at least a portion of the probe tip spring pin and at least a portion of the isolation resistor.

10. A probe tip spring pin apparatus, comprising:
a sleeve having a first crown tip;
a plunger, mechanically retained in the sleeve and having a second crown tip that is disposed opposite said first crown tip; and
a spring that biases the plunger with respect to the sleeve;
wherein the sleeve, spring and plunger provide a conductive path between the first and second crown tips.

11. The apparatus of claim 10, wherein the first crown tip has a diameter larger than that of the sleeve.

12. The apparatus of claim 10, wherein the first crown tip has an outwardly flared crown.

13. A method for constructing a probe apparatus, comprising:
forming a printed circuit board having at least first and second traces;
forming a via in the printed circuit board, the via being electrically coupled to the first and second traces;
drilling upper and lower blind plated holes, respectively intersecting the first and second traces;
plating the upper and lower blind plated holes; and
inserting a probe tip spring pin in the upper blind plated hole.

14. The method of claim 13, further comprising inserting a fixed pin in the lower blind plated hole.

15. The method of claim 14, further comprising soldering the probe tip spring pin in the upper blind plated hole and soldering the fixed pin in the lower blind plated hole.

16. A probe apparatus, comprising:
a printed circuit board having first and second traces, a via that electrically couples the first and second traces, and upper and lower blind plated holes that respectively intersect the first and second traces; and
a probe tip spring pin retained within the upper blind plated hole.

17. The apparatus of claim 16, wherein the first and second traces are inner traces of the printed circuit board, and wherein the via is a buried via in the printed circuit board.

18. The apparatus of claim 16, further comprising a fixed pin retained within the lower blind plated hole.

19. The apparatus of claim 18, wherein the probe tip spring pin is press fit into the upper blind plated hole and the fixed pin is press fit into the lower blind plated hole.

20. The apparatus of claim 16, wherein the probe tip spring pin is soldered into the upper blind plated hole and the fixed pin is soldered into the lower blind plated hole.

21. The apparatus of claim 16, wherein the probe tip spring pin is comprised of a sleeve, the sleeve mechanically retaining a plunger, the plunger having a first crown tip and the sleeve having a second crown tip, the second crown tip being inserted in the upper blind plated hole.

22. The apparatus of claim 21, wherein the second crown tip has a diameter larger than that of the sleeve.

23. The apparatus of claim 21, wherein the second crown tip has an outwardly flared crown.

24. A kit for making a probe to probe a grid array package comprising:
a substrate with a plurality of holes therein;
a mechanism to mechanically couple the substrate to a printed circuit board; and
a plurality of probe tip spring pin assemblies that are sized to be fit into the holes in the substrate.

25. The kit of claim 24, wherein ones of the probe tip spring pin assemblies comprise:
a probe tip spring pin;
an isolation resistor, electrically coupled to the probe tip spring pin;
a wire, electrically coupled to the isolation resistor; and
non-conductive sheathing surrounding at least a portion of the probe tip spring pin and at least a portion of the isolation resistor.

26. The kit of claim 24, wherein the mechanism to couple the substrate to the printed circuit board is pre-assembled on the substrate.
